(19) United States
(12) Patent Application Publication
(10) Pub. No.: US 2009/0316836 A1
(43) Pub. Date: Dec. 24, 2009

(54) SINGLE-WIRE, SERIAL, DAISY-CHAIN DIGITAL COMMUNICATION NETWORK AND COMMUNICATION METHOD THEREOF

(75) Inventor: Hung-Thung Wang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: GREEN MARK TECHNOLOGY INC., Taipei County (TW)

(21) Appl. No.: 12/107,786

(22) Filed: Apr. 23, 2008

(51) Int. Cl. H04L 27/00; H04L 27/06; H03D 1/00

(52) U.S. Cl. 375/340; 375/316; 375/344

(57) ABSTRACT

A digital communication network including several receivers and a communication method for the digital communication network are provided. Each of the receivers includes a first port and a second port. The first port of the first receiver is coupled to the microcontroller. The first port of each of the receivers except the first receiver is coupled to the second port of the previous receiver. Each receiver further includes a chain register. The chain registers of the receivers are mutually connected through the first ports and the second ports, forming a virtual global queue. By utilizing the characteristics of the virtual global queue, the system and the method achieve bi-directional, single-wire, serial communication without the encumbrance of assigning addresses or identification codes to the receivers.

### BACKGROUND OF THE INVENTION

1. Field of the Invention

The present invention relates to a digital communication network. More particularly, the present invention relates to a single-wire, serial, daisy-chain digital communication network and its communication method.

2. Description of the Related Art

There are three topological structures for a digital communication network where there is one master device and a plurality of slave (receiver) devices. A slave device typically receives instructions from the master and performs certain functions accordingly.

FIG. 1 illustrates a typical star structure. For a wired star structure, a plurality of receiver devices, R1-Rn, are communicating with the master device 110, each receiver via a separate communication channel. Receiver ID or address scheme is generally not required.

FIG. 2 illustrates a typical bus structure. A common communication channel 220 is shared by all receiver devices R1-Rn. Receiver ID or address is necessary for the data transmitted by the master device 210 to reach its intended receiver device. Typically, each receiver device has to be assigned or programmed with a unique device ID in the field when the communication network is set up initially.

FIG. 3 illustrates a typical daisy-chain structure. The master device 310 and a plurality of receiver devices R1-Rn are connected in a daisy-chain style. Each receiver devices is connected to one and only one upstream receiver device and one and only one down-stream receiver device. Each receiver device receives data from its upstream device and transmits to its down-stream device if necessary. In general, this daisy-chain structure requires individual receiver ID or address for the master device 310 to communicate with an intended receiver device exclusively.

There are many further classifications of digital communication networks. For example, there is parallel data transmission vs. serial data transmission. There is chip-select-line addressing vs. protocol addressing. There is implicit clock (self-clocking) transmission vs. separate clock-line transmission.

Many high-speed communication systems utilize a clock line to assist the receivers to read the data at the right timing. FIG. 4 shows a series of data pulses 401, which can be interpreted differently with different synchronizing clocks. With a synchronizing clock 402, the data is received and interpreted as “1011011100100”. With another synchronizing clock 404, the data is received as “01011010”.

Some well-known serial data-bus communication standards are I²C, SMBus, RS-485, LVDS, USB 2.0, and 1-Wire. I²C and SMBus feature two-wire (data and clock) communication and 7-bit address space. RS-485, LVDS, and USB 2.0 feature two-wire (data and clock) communication and differential signalling. 1-Wire is a trademark of Maxim Integrated Products, Inc. It features a single-wire communication and 48-bit address space.

### SUMMARY OF THE INVENTION

In a large-scale light-emitting diode (LED) lighting system, there is a need to control the on/off state, color or brightness of a plurality of LED lamps with the minimal number of data communication wires and also eliminates the need of individual receiver ID or address scheme. The elimination of address or device ID enables the use of mass-produced identical devices without the need for field address programming.

Accordingly, the present invention relates to a single-wire, serial, daisy-chain digital communication network. This digital communication network includes several receivers. Each of the receivers is identical in embodiment and function and works without any device addresses, device identification codes, or chip-select lines.

The present invention is also directed to a communication method for the digital communication network mentioned above. The method enables bi-directional single-wire communication and simplifies installation and maintenance of the digital communication network.

According to an embodiment of the present invention, a digital communication network is provided. The system includes a plurality of receivers which receive commands and control data from a microprocessor and report back to the microprocessor. Each of the receivers includes a first port and a second port. The first port of the first receiver is coupled to the microcontroller. The first port of each of the receivers except the first receiver is coupled to the second port of the previous receiver. Each of the receivers is configured to receive a bit pattern from the first port and decode the bit pattern into a data bit or a latch bit. If the bit pattern is decoded as a data bit, the receiver stores the N most recent data bits and outputs the (N+1)-th most recent data bit in the form of the bit pattern to the second port. N is a predetermined positive integer. If the bit pattern is decoded as a latch bit, the receiver processes the N most recent data bits as a data word and outputs the latch bit in the form of the bit pattern to the second port.

In this embodiment, a bit pattern includes a header pattern and a payload pattern. Each of the receivers differentiates the bit pattern from background noises by the header pattern and synchronizes a local clock signal to the header pattern. Each of the receivers decodes the payload pattern into a data bit or a latch bit.

In this embodiment, before synchronization, the frequency of the local clock signal is initially determined according to the resistance of a resistor. The resistor may be an external resistor. The resistors of the receivers have the same resistance. After synchronization, the local clock signal is used to decode the payload pattern and retransmit a stored bit pattern to the second port.

In this embodiment, the digital communication network further supports a report feedback protocol. During the feedback the roles of the first port and the second port are exchanged. A specific command word initializes the feedback protocol and another command word terminates the feedback protocol.

In this embodiment, each of the receivers includes a bypass circuit. The bypass circuit is coupled between the first port and the second port. The bypass circuit compares a power supply voltage of the receiver against a reference voltage. When the power supply voltage is lower than the reference voltage, the bypass circuit directly connects the first port and the second port so that the receiver is still able to forward bit patterns across its ports. The bypass circuit is powered by the electrical energy of the bit pattern itself.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram showing a conventional digital communication network in a star structure.

FIG. 2 is a schematic diagram showing a conventional digital communication network in a bus structure.

FIG. 3 is a schematic diagram showing a conventional digital communication network in a daisy-chain structure.

FIG. 4 shows how a synchronizing clock helps a receiver to decode the data transmitted correctly.

FIG. 5 is a schematic diagram showing a digital communication network according to an embodiment of the present invention.

FIG. 6 is a schematic diagram showing the waveform of a bit pattern according to an embodiment of the present invention.

FIG. 7 is a schematic diagram showing part of the structure of a receiver according to an embodiment of the present invention.

FIG. 8 is a flow chart of a communication method according to an embodiment of the present invention.

FIG. 9 is a schematic diagram showing the circuit of a clock generator according to an embodiment of the present invention.

FIG. 10 is a schematic diagram showing the circuit of a tri-state inverter of the clock generator in FIG. 9.

FIG. 11 is a schematic diagram showing a bypass circuit of a receiver according to an embodiment of the present invention.

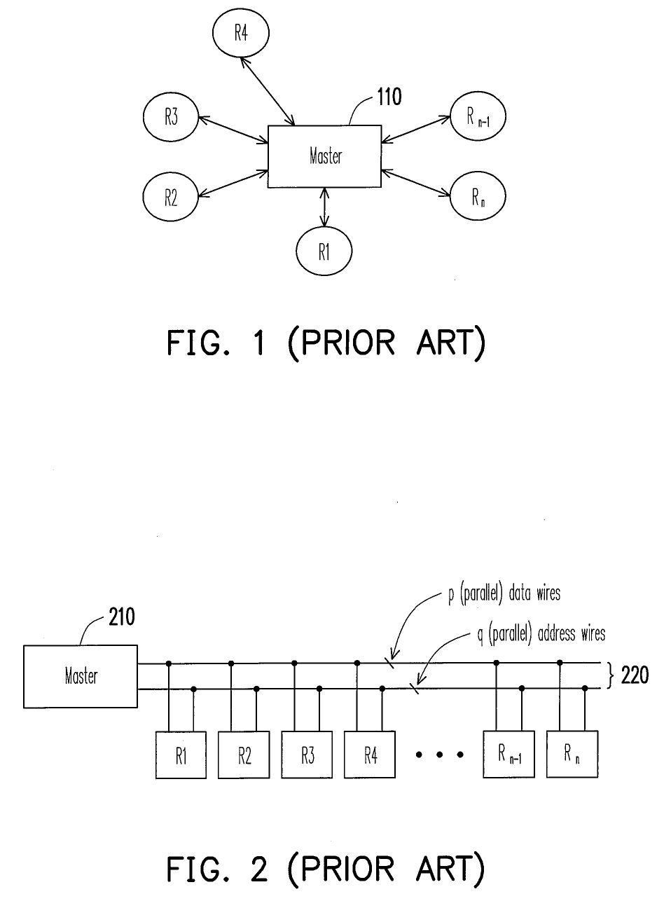

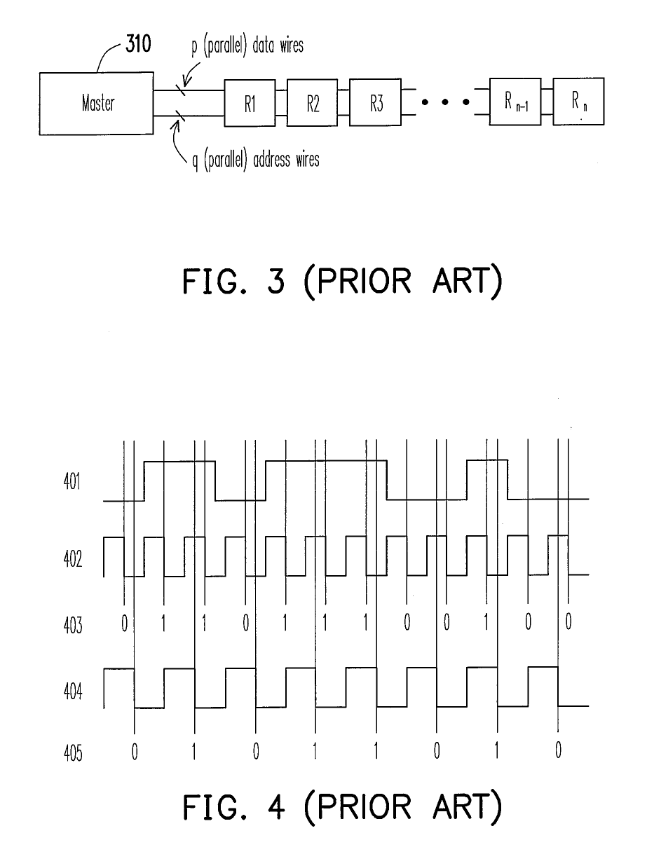

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

The present invention discloses a single-wire, serial, daisy-chain digital communication network which requires no receiver ID or address scheme.

Further, a preferred embodiment of the invention features a bi-directional communication method between a master device and a plurality of receiver devices.

An alternative embodiment of the invention includes a bypass function such that when a receiver device is damaged or powered down, a by-pass path is established to keep the communication between the master and other receiver devices intact.

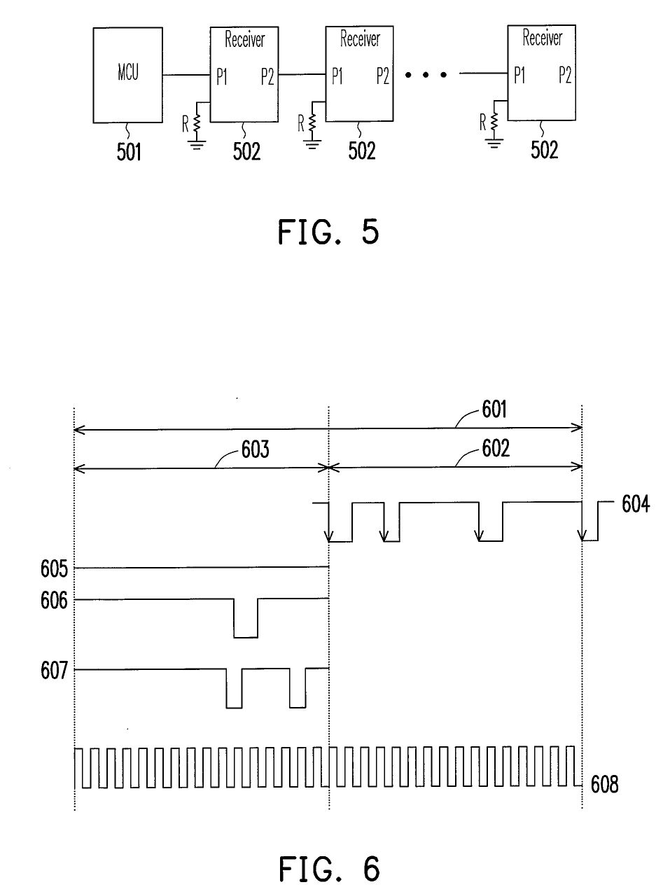

FIG. 5 is a schematic diagram showing a digital communication network according to an embodiment of the present invention. The system includes several receivers 502 controlled by a microcontroller (MCU) 501. For example, each receiver 502 may control several light-emitting diode (LED) lamps (not shown). The receivers 502 are connected in a daisy chain style. Each receiver 502 includes a first port P1 and a second port P2. The first port P1 of the first receiver is coupled to the MCU 501. The first port P1 of each receiver 502 except the first receiver is coupled to the second port P2 of the previous receiver. Each receiver 502 is identical in function and structure. The MCU identifies the individual receiver only by its sequential location in the daisy chain.

The communication protocol used by the MCU 501 and the receivers 502 is embedded in the timing nature of bit patterns. The MCU transmits bit patterns to the first port P1 of the first receiver. Each receiver 502 is configured to receive bit patterns entering into first port P1, decode the bit patterns, and then, if necessary, forward the bit patterns to the next receiver. Alternatively the MCU 501 may initiate a report feedback protocol in which the receivers 502 transmits bit patterns to the MCU 501 by receiving bit patterns from the second port P2 and then forwarding the bit patterns to the first port P1. In both cases, the receivers 502 also act as decoders and repeaters for bit patterns. Each first port P1 and each second port P2 has only one transmission wire, achieving bi-directional single-wire communication.

FIG. 6 is a schematic diagram showing the waveform of a typical bit pattern 601. The bit pattern 601 includes a header pattern 602 and a payload pattern 603. The duration of the payload pattern 603 is the same as the duration of the header pattern 602. Each receiver 502 differentiates the bit pattern 601 from non-signal background noises by qualifying the header pattern 602 first. Each receiver 502 also synchronizes its local clock signal with the header pattern 602 because it is very possible that the local clock frequency of a receiver 502 is different from the clock frequency of the MCU 501. The synchronization is performed anew for each bit pattern, thus eliminating the possibility of accumulating timing error.

The data or command is carried in the payload pattern 603. Each receiver 502 is configured to decode the payload pattern 603 into a data bit or a special latch bit. More details about the synchronization, the decoding, and the waveforms in FIG. 6 will be discussed below.

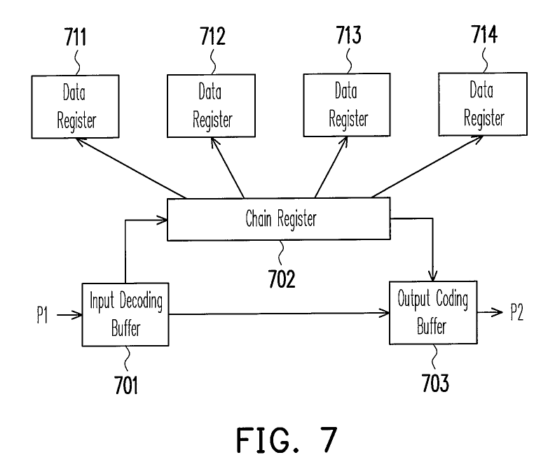

FIG. 7 is a schematic diagram showing part of the circuit of a receiver 502. Each receiver 502 further includes an input decoding buffer 701, a chain register 702, an output coding buffer 703, and several data registers 711-714. The input decoding buffer 701 is coupled to the first port P1. The chain register 702 is coupled to the input decoding buffer 701 and the data registers 711-714. The output coding buffer 703 is coupled among the input decoding buffer 701, the chain register 702, and the second port P2. The components in FIG. 7 will be discussed in more details below.

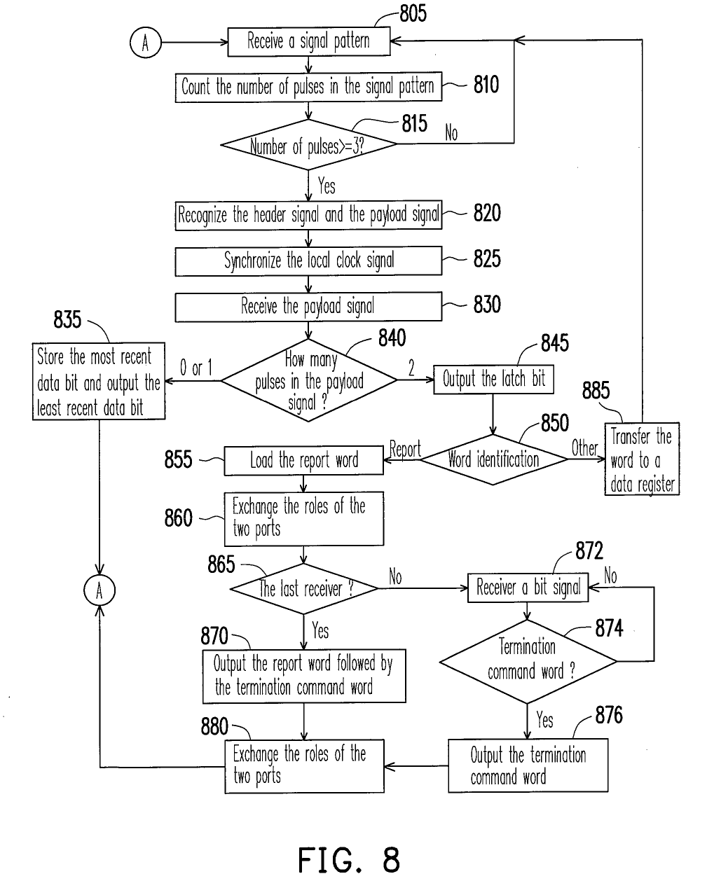

FIG. 8 is a flow chart of the communication method executed by each receiver 502 in this embodiment. The flow begins at step 805. The input decoding buffer 701 decodes the bit pattern 601. First, the input decoding buffer 701 has to qualify the bit pattern 601 as valid signal. The input decoding buffer 701 receives a signal pattern from the first port P1 (step 805) and counts the number of pulses in the signal pattern in a predetermined period (step 810). For example, the predetermined period may be one millisecond. Next, the input decoding buffer 701 checks whether the counted number of pulses is greater than or equal to a predetermined number. For example, the predetermined number is specified as 3 (step 815). If it is a true case, the input decoding buffer 701 qualifies the current signal pattern as a valid header pattern 602 and receives the next signal pattern immediately following the current signal pattern as the payload pattern 603 (step 820). If the number of pulses is less than the predetermined number, the current signal pattern is regarded as non-signal noises and the flow returns to step 805.

Next, the receiver 502 synchronizes its local clock signal with the header pattern 602 (step 825). The duration of the header pattern 602 is defined by a predetermined number of consecutive pulse edges of a predetermined type. The predetermined type may be a rising edge or a falling edge. For example, the duration is defined by four consecutive falling edges in this embodiment. The waveform 604 in FIG. 6 is an exemplary waveform of the header pattern 602. In other embodiments of the present invention, the duration of the header pattern 602 may be defined by a predetermined number of consecutive rising edges as well.

The receiver 502 synchronizes the local clock signal by adjusting the frequency of the local clock signal so that the local clock signal has a predetermined number of pulses in the duration of the header pattern 602. For example, the predetermined number may be 16. The waveform 608 in FIG. 6 is an exemplary waveform of the synchronized local clock signal in this case. The technical details of adjusting the local clock frequency is well-known and are not discussed here.

Next, the input decoding buffer 701 receives the payload pattern (step 830). Since the header pattern 602 and the payload pattern 603 have the same duration, the duration of the payload pattern 603 can be measured using the synchronized local clock signal. The payload pattern 603 is decoded according to its number of pulses (step 840). If the payload pattern 603 has no pulse, as shown by the waveform 605 in FIG. 6, the input decoding buffer 701 recognizes the payload pattern 603 as a data bit with value 1. If the payload pattern 603 has one pulse, as shown by the waveform 606 in FIG. 6, the input decoding buffer 701 recognizes the payload pattern 603 as a data bit with value 0. If the payload pattern 603 has two pulses, as shown by the waveform 607 in FIG. 6, the input decoding buffer 701 recognizes the payload pattern 603 as a special latch bit.

If the payload pattern 603 is recognized as a data bit, no matter the value is 0 or 1, the flow proceeds to step 835. The input decoding buffer 701 provides the decoded data bit value to the chain register 702. The chain register 702 has a predetermined number of bit cells. For example, the predetermined number may be 9. Each bit cell is for storing one data bit. Upon receiving the most recent data bit, the chain register 702 shifts the data bit stored in each bit cell to the next bit cell, and then stores the most recent data bit in the first bit cell. It can be easily seen that the chain register 702 stores the 9 most recent data bits from the input decoding buffer 701. The data bit previously stored in the last bit cell, namely the 10th most recent data bit or the least recent data bit, is shifted out of the chain register 702 and into the output coding buffer 703. In other embodiments of the present invention, the chain register 702 may include more or less bit cells.

The output coding buffer 703 receives the least recent data bit from the chain register 702, re-constructs it into a bit pattern using the synchronized local clock signal as its timing reference, and then outputs the bit pattern to the second port P2. After the transmission of the least recent data bit, the flow returns to step 805 to receive the next bit pattern.

If the input decoding buffer 701 decodes the bit pattern as a latch bit at step 840, the flow proceeds to step 845. A latch bit takes a different path from that of a data bit. The input decoding buffer 701 outputs the latch bit directly to the output coding buffer 703, not to the chain register 702. The output coding buffer 703 re-constructs the latch bit into a bit pattern using the synchronized local clock signal as the timing reference (step 845) and then outputs the bit pattern to the second port P2.

Whenever the MCU 501 sends a data bit to the first receiver 502, this data bit becomes the most recent data bit of the first receiver. The least recent data bit of the first receiver becomes the most recent data bit of the second receiver. The least recent data bit of the second receiver becomes the most recent data bit of the third receiver, and so on. In effect, the chain registers of all the receivers 502 connect in series to form a long queue for shift registers.

In the protocols of the communication method in this embodiment, 9 data bits constitute a word. The communication method has a forward protocol as well as a report feedback protocol. The forward protocol is used by the MCU 501 to send control information or commands to the receivers 502. For example, the MCU 501 may control several thousands of receivers. As shown in FIG. 7, each receiver in turn, controls four LED lamps. When the MCU 501 needs to send control words to all the lamps, it sends the words out in several iterations. The control words may contain control information for the lamps, such as LED current setting, or PWM dimming level setting.

In the first iteration, the MCU sends the control word for the first lamp controlled by the last receiver, and then sends the control word for the first lamp controlled by the next-to-last receiver, and so on, until finally the MCU sends out the control word for the first lamp controlled by the first receiver. At this moment, the control words fully occupy the chain registers of all the receivers. Each receiver has the control word for its first lamp stored in its chain register.

Next, the MCU 501 sends a latch bit to the first receiver 502. The latch bit means the receiver must process the word in its chain register 702. The first receiver 502 identifies the word in the chain register 702 (step 850). If the word is not any special command word, it is treated as a control word. Therefore the first receiver transfers the control word from the chain register 702 to the first data register 711 (step 885). Meanwhile, the latch bit is already forwarded to the second receiver at step 845. In this way, the latch bit is forwarded through all the receivers along the daisy chain so that the control word in each receiver is moved from the chain register 702 to the first data register 711.

In the second iteration, the MCU 501 sends out control words for the second lamp controlled by each receiver 502 and the control words are stored into the second data register 712 of each receiver 502. The following iterations proceed in a similar way. Finally the control words for all the LED lamps are stored into their corresponding data registers.

The report feedback protocol is used for the receivers 502 to report important information to the MCU 501. For example, the reported information may be fault status of the LED lamps. The MCU 501 initiates the report feedback protocol by transmitting a series of report command words. The number of the report command words in the series is equal to the number of receivers so that each receiver has its own copy. And then the MCU 501 sends out a latch bit. Each receiver identifies the word in the chain register 702 and determines that the word is the report command word (step 850). Therefore the flow proceeds to step 855.

After identifying the report command word, each receiver 502 loads a report word into its chain register 702 (step 855) and then exchanges the roles of its first port P1 and second port P2 (step 860). Exchanging the roles of the ports means coupling the input decoding buffer 701 to the second port P2 and couple the output coding buffer 703 to the first port P1 so that the receiver 502 receives bit patterns from the second port P2 and forwards bit patterns to the first port P1. This reverses the transmission direction of the daisy chain.

The last receiver of the daisy chain has a special role to start the backward transmission of the report words. The user of the digital communication network may pull high or pull low an input pin of a receiver device to a predetermined voltage level so that this receiver knows it is the last receiver. After exchanging the roles of its two I/O ports, each receiver checks if it is the last one in the daisy chain (step 865). If it is the last one, the last receiver outputs the report word followed by a termination command word through its chain register 702 and its output coding buffer 703 to the first port P1 (step 870).

Like the marching of bit patterns in the forward protocol, the transmission of the last receiver triggers the transmission of the previous receivers. Each receiver provides a report word. The last receiver provides a report word and a termination command word. The series of the report words and the termination command word passes through the virtual shift register queue to the MCU 501. The first report word received by the MCU 501 comes from the first receiver 502, which is closest to the MCU 501. The second report word received by the MCU 501 comes from the second receiver 502, and so on. By the receipt order, the MCU 501 knows exactly the origin of each report word. After outputting the termination command word, the last receiver exchanges the roles of its two I/O ports again by coupling the input decoding buffer 701 back to the first port P1 and coupling the output coding buffer 703 back to the second port P2 in order to restore the transmission direction (step 880). The flow returns to step 805 to resume the forward protocol.

If the check at step 865 reveals that the receiver is not the last one, the receiver begins to wait for bit patterns from the next receiver in the daisy chain. The receiver receives a bit pattern from the second port P2 (step 872), stores the decoded data bit as the most recent data bit in the chain register 702, and outputs the least recent data bit from the chain register 702 to the previous (upstream) receiver. Next, the receiver checks if the data bits stored in the chain register 702 constitute the termination command word, which comes from the last receiver (step 874). If the termination command word has not yet entered the chain register 702, the report feedback protocol is still in effect and the flow returns to step 872 to receive the next bit pattern from the next (down-stream) receiver. If the termination command word has entered the chain register 702, the receiver outputs the termination command word through the output coding buffer 703 to the first port P1 (step 876). Next, the receiver exchanges the roles of its first port P1 and second port P2 again to restore its transmission direction (step 880). Now the report feedback protocol is over for this receiver. The flow returns to step 805 to resume the forward protocol.

From the discussions above, it can be easily seen that the order of each receiver 502 in the daisy chain serves as an implicit address of the receiver. Consequently the communication method in this embodiment provides a way of bi-directional transmission without the encumbrance of address or identification code.

Each receiver 502 synchronizes its local clock signal with each header pattern 602. Initially, before synchronization, the frequency of the local clock signal may be determined according to the resistance of a resistor. Each receiver may be implemented in the form of an IC chip and the resistor may be an external resistor R coupled to the chip by the user, as shown in FIG. 5. In this case, the user can easily adjust the initial local clock frequency by controlling the resistance of the external resistor R. To minimize timing deviation, it is preferable that the external resistors of the receivers 502 have the same resistance.

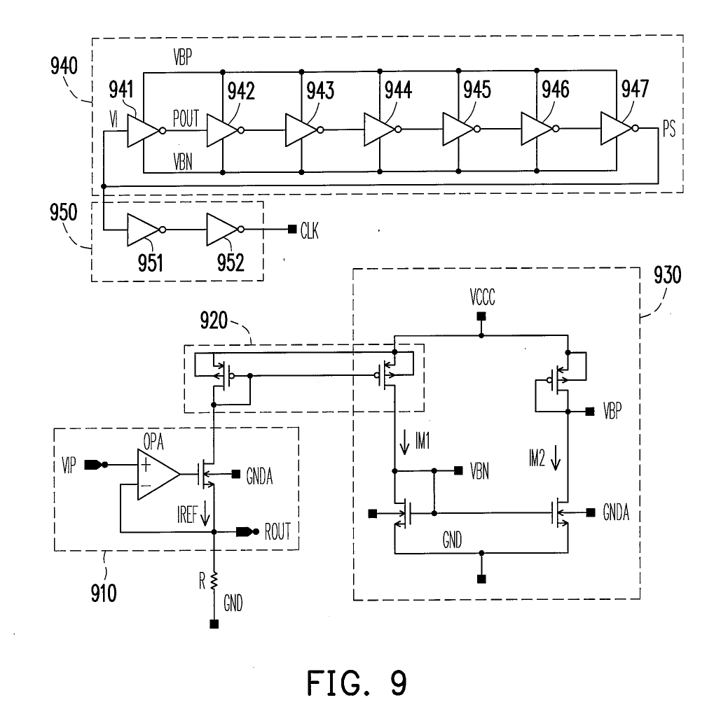

Each receiver 502 includes a clock generator for providing the local clock signal. FIG. 9 is a schematic diagram showing the circuit of the clock generator according to this embodiment. The clock generator includes a current generator 910, two current mirrors 920 and 930, a positive feedback oscillator 940, and a signal shaper 950. The current generator 910 is coupled to the external resistor R. The current mirror 920 is coupled to the current generator 910. The current mirror 930 is coupled to the current mirror 920. The positive feedback oscillator 940 is coupled to the current mirror 930. The signal shaper 950 is coupled to the positive feedback oscillator 940.

The current generator 910 includes an operational amplifier OPA. VIP is a constant reference voltage. The virtual short circuit of the operational amplifier OPA makes the voltage at ROUT equal to VIP. Consequently the current generator 910 provides a reference current IREF which is inversely proportional to the resistance of the external resistor R. The current mirror 920 provides a mirror current IM1 according to the reference current IREF. The current mirror 930 provides another mirror current IM2 according to the mirror current IM1. The current mirror 930 also provides a control voltage VBN according to the mirror current IM1 and another control voltage VBP according to the mirror current IM2. The positive feedback oscillator 940 providing a periodic signal PS whose frequency depends on the control voltages VBN and VBP (details later). The inverters 951 and 952 of the signal shaper 950 shape the periodic signal PS into the local clock signal CLK.

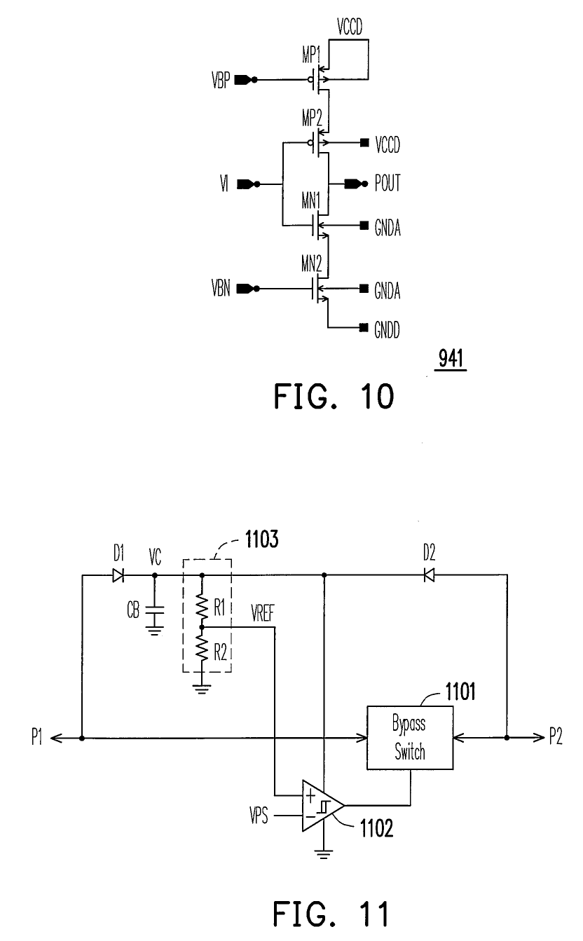

The positive feedback oscillator 940 includes seven tri-state inverters 941-947. The tri-state inverters 941-947 are identical and are connected in series. Take the first tri-state inverter 941 as an example. FIG. 10 is a schematic diagram showing the circuit of the tri-state inverter 941, which includes four metal oxide semiconductor field effect transistors (MOSFETs). MP1 and MP2 are p-channel MOSFETs. MN1 and MN2 are n-channel MOSFETs.

The resistance of the resistor R determines the levels of the currents IREF, IM1 and IM2. The mirror currents IM1 and IM2 determine the levels of the control voltages VBN and VBP, respectively. The control voltage VBP determines the current through the MOSFET MP1. Similarly, the control voltage VBN determines the current through the MOSFET MN2. The currents through MP1 and MN2 determine the switching speed of the output of the tri-state inverter 941. The tri-state inverters 941-947 are identical. Therefore the frequency of the local clock signal CLK is determined according to the resistance of the external resistor R. In some other embodiments of the present invention, the positive feedback oscillator 940 may include more or less tri-state inverters.

The receivers in this embodiment support fault tolerance. When a receiver somehow gets damaged or loses its power supply, the receiver is still able to forward bit patterns between its I/O ports to maintain the communication of the other receivers in the daisy chain. That is because each receiver includes a bypass circuit.

FIG. 11 is a schematic diagram showing the bypass circuit according to this embodiment. The bypass circuit is coupled between the first port P1 and the second port P2. The bypass circuit includes two diodes D1 and D2, a capacitor CB, two resistors R1 and R2, a bypass switch 1101, and a comparator 1102. The anode of the diode D1 is coupled to the first port P1. The anode of the diode D2 is coupled to the second port P2. The cathode of the diode D2 is coupled to the cathode of the diode D1. The capacitor CB has two ends. The upper end is coupled to the cathodes of the diodes D1 and D2. The lower end is grounded. The upper end of the capacitor CB provides a capacitor voltage VC. The voltage converter 1103 includes the resistors R1 and R2 and provides a reference voltage VREF which is directly proportional to the capacitor voltage VC. The ratio of VC to VREF is predetermined by the resistances of R1 and R2. The comparator 1102 is coupled to the voltage converter 1103 for comparing the reference voltage VREF with a power supply voltage VPS of the receiver. The bypass switch 1101 is coupled to the first port P1, the second port P2, and the comparator 1102. The bypass switch 1101 is configured to connect or disconnect the first port P1 and the second port P2 in response to the output of the comparator 1102.

During the forward protocol, bit patterns from the first port P1 charges the capacitor CB and the capacitor CB provides the capacitor voltage VC. The diode D1 prevents the capacitor CB from discharge and maintains the level of VC, which also maintains the level of VREF. In normal situations, the power supply voltage VPS is higher than the reference voltage VREF and the output of the comparator 1102 is at a logical low level. In response, the bypass switch 1101 disconnects the first port P1 and the second port P2. The two I/O ports P1 and P2 are not shorted and the forward protocol is executed as discussed above. The comparator 1102 is powered by the electric energy of the bit patterns from the first port P1 through the diode D1.

When the receiver is damaged or loses its power supply, the power supply voltage VPS becomes lower than the reference voltage VREF. The output of the comparator 1102 rises to a logical high level and triggers the bypass switch 1101 to connect the ports P1 and P2. Now the ports P1 and P2 are shorted. Although the receiver itself cannot process bit patterns, bit patterns from the first port P1 can propagate to the second port P2 unhindered.

As can be seen in FIG. 11, the bypass circuit is symmetric. During the report feedback protocol, the diode D2 replaces the diode D1 to charge the capacitor CB and supply power to the comparator 1102. The bypass circuit still works during the report feedback protocol. As mentioned above, the bypass circuit is powered entirely by bit patterns. Therefore the bypass circuit is still functional even if the receiver undergoes power failure.

In summary, this embodiment of the present invention provides a digital communication network and a communication method. The communication method is bi-directional and does not have to assign unique addresses or identification codes to the receivers in the digital communication network. The single-wire I/O ports reduce the cost of installation and maintenance. The clock generator determines the local clock frequency according to the resistance of a resistor. The system can adjust the overall communication clock speed by selecting proper resistor values for each receiver's clock resistor. Furthermore, the bypass circuit provides fault tolerance when a receiver is damaged or undergoes power failure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A digital communication network, comprising:
a plurality of receivers, wherein
each of the receivers comprises a first port and a second port, the first port of the first receiver is coupled to a microcontroller, the first port of each of the receivers except the first receiver is coupled to the second port of the previous receiver;
each of the receivers is configured to receive a bit pattern from the first port and decode the bit pattern into a data bit or a latch bit;
each of the receivers is further configured to store the N most recent data bits and outputs the (N+1)-th most recent data bit in the form of the bit pattern to the second port, wherein N is a predetermined positive integer;
each of the receivers is further configured to process the N most recent data bits and outputs the latch bit in the form of the bit pattern to the second port.

2. The digital communication network of claim 1, wherein each of the first ports and the second ports has only one transmission wire.

3. The digital communication network of claim 2, wherein each of the receivers is identical in embodiment and function and works without any device addresses, device identification codes, or chip-select lines.

4. The digital communication network of claim 1, wherein the bit pattern comprises a header pattern and a payload pattern, each of the receivers is configured to differentiate the bit pattern from background noises by the header pattern and synchronize a local clock signal with the header pattern, each of the receivers is also configured to decode the payload pattern into the data bit or the latch bit.

5. The digital communication network of claim 4, wherein each of the receivers is configured to receive a first signal pattern from the first port and counts the number of pulses in the first signal pattern in a predetermined period, the receiver is configured to recognize the first signal pattern as the header pattern and a second signal pattern immediately following the first signal pattern as the payload pattern if the counted number of pulses is greater than or equal to a first predetermined number.

6. The digital communication network of claim 5, wherein the duration of the header pattern is defined by a second predetermined number of consecutive pulse edges of a predetermined type and the duration of the payload pattern is the same as the duration of the header pattern, the receiver is configured to synchronize the local clock signal by adjusting the frequency of the local clock signal so that the local clock signal comprises a third predetermined number of pulses in the duration of the header pattern, the receiver is also configured to decode the payload pattern and outputs the (N+1)-th most recent data bit and the latch bit according to the synchronized local clock signal.

7. The digital communication network of claim 4, wherein each of the receivers is configured to determine the frequency of the local clock signal according to the resistance of a resistor, the resistors of the receivers have the same resistance.

8. The digital communication network of claim 7, wherein each of the receivers comprises a clock generator for providing the local clock signal and the clock generator comprises:
a current generator for providing a reference current proportional to the resistance of the resistor;
a first current mirror coupled to the current generator for providing a first mirror current according to the reference current;
a second current mirror coupled to the first current mirror for providing a second mirror current according to the first mirror current, the second current mirror further providing a first control voltage according to the first mirror current and a second control voltage according to the second mirror current;
a positive feedback oscillator coupled to the second current mirror for providing a periodic signal whose frequency depends on the first control voltage and the second control voltage; and
a signal shaper coupled to the positive feedback oscillator for shaping the periodic signal into the local clock signal.

9. The digital communication network of claim 4, wherein each of the receivers is configured to decode the payload pattern into the data bit or the latch bit according to the number of pulses in the payload pattern, each of the receivers is also configured to determine the value of the data bit according to the number of pulses in the payload pattern.

10. The digital communication network of claim 4, wherein each of the receivers further comprises:
an input decoding buffer coupled to the first port for receiving the bit pattern from the first port and decoding the bit pattern into the data bit or the latch bit;
a chain register comprising N bit cells for storing the N most recent data bits, coupled to the input decoding buffer and configured to shift the content of each of the bit cells to the next bit cell, outputs the content previously stored in the last bit cell as the (N+1)-th most recent data bit, and store the most recent data bit received from the input decoding buffer into the first bit cell; and
an output coding buffer coupled to the input decoding buffer, the chain register, and the second port for outputting the (N+1)-th most recent data bit and the latch bit in the form of the bit pattern to the second port.

11. The digital communication network of claim 10, wherein each of the receivers further comprises a data register coupled to the chain register, the receiver is configured to transfer the contents of the chain register into the data register if the payload pattern is decoded into the latch bit.

12. The digital communication network of claim 10, wherein
when the contents of the chain register constitute a first command word and the bit pattern is decoded into the latch bit, each of the receivers is configured to load a report word into the chain register, output the latch bit to the second port, and couple the input decoding buffer to the second port and couple the output coding buffer to the first port;
the last receiver is further configured to output the report word followed by a second command word through the chain register and the output coding buffer to the first port;
when the contents of the chain register constitute the second command word, each of the receivers is further configured to output the second command word through the output coding buffer to the first port and then couple the input decoding buffer back to the first port and couple the output coding buffer back to the second port.

13. The digital communication network of claim 1, wherein each of the receivers further comprises:
a bypass circuit coupled between the first port and the second port and configured to connect the first port and the second port when a power supply voltage of the receiver is lower than a reference voltage, wherein the bypass circuit is powered by the bit pattern.

14. The digital communication network of claim 13, wherein the bypass circuit comprises:
a first diode with a first anode and a first cathode, wherein the first anode is coupled to the first port;
a second diode with a second anode and a second cathode, wherein the second anode is coupled to the second port and the second cathode is coupled to the first cathode;
a capacitor with a first end and a second end, the first end coupled to the first cathode and the second cathode, the second end grounded, wherein a capacitor voltage is provided at the first end;
a voltage converter coupled to the capacitor for providing a reference voltage which is directly proportional to the capacitor voltage;
a comparator coupled to the voltage converter and configured to compare the reference voltage with the power supply voltage; and
a bypass switch coupled to the first port, the second port, and the comparator, configured to connect or disconnect the first port and the second port in response to the output of the comparator.

15. A communication method for a digital communication network, comprising:
(a) receiving a bit pattern from a first port and decoding the bit pattern into a data bit or a latch bit;
(b) storing the N most recent data bits and outputting the (N+1)-th most recent data bit in the form of the bit pattern to a second port, wherein N is a predetermined positive integer; and
(c) processing the N most recent data bits and outputting the latch bit in the form of the bit pattern to the second port.

16. The communication method of claim 15, wherein the bit pattern comprises a header pattern and a payload pattern, and step (a) comprises:
(a1) differentiating the bit pattern from background noises by the header pattern;
(a2) synchronizing a local clock signal with the header pattern; and
(a3) decoding the payload pattern into the data bit or the latch bit.

17. The communication method of claim 16, wherein step (a1) comprises:
receiving a first signal pattern from the first port;
counting the number of pulses in the first signal pattern in a predetermined period;
if the counted number of pulses is greater than or equal to a first predetermined number, recognizing the first signal pattern as the header pattern and a second signal pattern immediately following the first signal pattern as the payload pattern.

18. The communication method of claim 17, wherein the duration of the header pattern is defined by a second predetermined number of consecutive pulse edges of a predetermined type and the duration of the payload pattern is the same as the duration of the header pattern, the communication method further comprises:
synchronizing the local clock signal by adjusting the frequency of the local clock signal so that the local clock signal comprises a third predetermined number of pulses in the duration of the header pattern; and
decoding the payload pattern and outputting the (N+1)-th most recent data bit and the latch bit according to the synchronized local clock signal.

19. The communication method of claim 16, wherein step (a3) comprises:
decoding the payload pattern into the data bit or the latch bit according to the
number of pulses in the payload pattern; and
determining the value of the data bit according to the number of pulses in the payload pattern.

20. The communication method of claim 16, further comprising:
when the N most recent data bits constitute a first command word and the bit pattern is decoded into the latch Bit, replacing the N most recent data bits with a report word, outputting the latch bit to the second port, and exchanging the roles of the first port and the second port;
if the communication method is executed by the last receiver of the digital communication network, outputting the report word followed by a second command word serially to the first port;
when the N most recent data bits constitute the second command word, outputting the second command word serially to the first port and then exchanging the roles of the first port and the second port again.

21. The communication method of claim 15, further comprising:
connecting the first port and the second port when a power supply voltage is lower than a reference voltage.
